(19) United States
(12) Patent Application Publication
(10) Pub. No.: US 2007/0041233 A1
(43) Pub. Date: Feb. 22, 2007

(54) Wake-up of ferroelectric thin films for probe storage

(75) Inventors: Andreas Karl Roelofs, Pittsburgh, PA (US); Martin Gerard Forrester, Murrysville, PA (US); Joachim Walter Ahner, Pittsburgh, PA (US)

Correspondence Address: PIETRAGALLO, BOSICK & GORDON LLP, ONE OXFORD CENTRE, 38TH FLOOR, 301 GRANT STREET, PITTSBURGH, PA, 15219-6404, US

(73) Assignee: Seagate Technology LLC, Scotts Valley, CA (US)

(21) Appl. No.: 11/207,863

(22) Filed: Aug. 19, 2005

(51) Int. Cl. G11C 11/22

(52) U.S. Cl. 365/145

(57) ABSTRACT

A method for improving the stability of ferroelectric storage devices comprises: providing a ferroelectric storage medium including a film of ferroelectric material; and repeatedly applying a voltage to the film of ferroelectric material to improve the stability of polarized bits in the film of ferroelectric material. An apparatus that is used to perform the method is also provided.

### FIELD OF THE INVENTION

This invention relates to ferroelectric thin film devices, and more particularly to data storage devices that include ferroelectric storage media.

### BACKGROUND OF THE INVENTION

The reversibility of the spontaneous polarization makes ferroelectric materials promising candidates for use as storage media in future non-volatile memory devices. Binary information is stored in the two remanent polarization states by applying an appropriate switching voltage to a ferroelectric capacitor. After poling the capacitor into the desired state, the polarization is preserved without the application of an external field.

Ferroelectric materials can form the basis for data storage devices, where digital “1” and “0” levels are represented by the electric polarization of a ferroelectric film pointing “up” or “down”. Storage devices based on a ferroelectric storage medium include Ferroelectric Random Access Memory (FeRAM) and scanning-probe storage systems (“FE-probe”).

In a FeRAM memory cell the essential storage element includes a thin ferroelectric film sandwiched between fixed, conductive electrodes. To write a bit to such a cell, a voltage pulse of either positive or negative polarity is applied between the electrodes in order to switch the internal polarization of the ferroelectric film to the “up” or “down” state, respectively. To read back the data from the FeRAM cell, a read voltage of a certain polarity (e.g. positive) is applied, which switches the polarization of the ferroelectric film in cells storing a “0” (“down” polarization), while having no effect in cells storing a “1”. A sense amplifier measures the charge flow that results when the polarization switches, so that a current pulse is observed for cells which stored a “0”, but not for cells which stored a “1”, thus providing a destructive readback capability.

Probe storage devices have been proposed to provide small size, high capacity, low cost data storage devices. A probe storage device based on ferroelectric thin films uses one or more small, electrically conducting tips as movable top electrodes to store binary information in spatially localized domains. Binary “1's” and “0's” are stored in the media by causing the polarization of the ferroelectric film to point “up” or “down” in a spatially small region (domain) local to the electrode, by applying suitable voltages to the electrode. Data can then be read out by a variety of means, including sensing of piezoelectric surface displacement, measurement of local conductivity changes, or by sensing current flow during polarization reversal (destructive readout).

Upon cycling ferroelectric thin films between two polarization states, it has been found that the polarization increases as the number of voltage cycles increases. This is called the wake-up effect. Thus in order to achieve the full remanent polarization of a ferroelectric thin film, the film needs to be switched several times. The number of switching cycles to fully wake-up (or train) the film depends on the ferroelectric material as well as on the electrode material.

For integrated ferroelectric thin films placed between bottom and top electrodes (as in FeRAM), this is not an issue as the film can be switched several times prior to using the device. However, when using ferroelectric thin film media for probe-based high-density data storage (“FE-probe”), small bits written with an AFM tip into a non-trained area of a ferroelectric thin film show strong relaxation even at room temperature. For example, the bits may be stable for only several days.

There is a need for method and apparatus that can improve the stability of the remanent polarization of ferroelectric films in probe storage devices.

### SUMMARY OF THE INVENTION

This invention provides a method for improving the stability of ferroelectric storage devices comprising: providing a ferroelectric storage medium including a film of ferroelectric material; and repeatedly applying a voltage to the film of ferroelectric material to improve the stability of polarized bits in the film of ferroelectric material.

In another aspect, the invention provides an apparatus comprising: a ferroelectric storage medium including a film of ferroelectric material, first and second electrodes positioned on opposite sides of the film of ferroelectric material, wherein the first electrode is removable, and a voltage source for repeatedly applying a voltage to the first and second electrodes to improve the stability of polarized bits in the film of ferroelectric material.

The invention further encompasses an apparatus comprising a ferroelectric storage medium including a film of ferroelectric material, a plurality of electrodes positioned adjacent to a surface of the film of ferroelectric material, and a voltage source for repeatedly applying a voltage to the electrodes to improve the stability of polarized bits in the film of ferroelectric material.

### BRIEF DESCRIPTION OF THE DRAWINGS

FIG. 1 is an isometric view of a ferroelectric probe storage device that can be constructed and operated in accordance with the present invention.

FIG. 2 is a cross-sectional view of a portion of a ferroelectric storage medium.

FIG. 3 is a schematic illustration of one embodiment of a probe electrode, and its mechanical and electrical support structures.

FIG. 4 is a schematic side view of a ferroelectric storage medium.

FIG. 5 is a schematic side view of another ferroelectric storage medium.

FIG. 6 is a graph that illustrates the remanance polarization after repeated applications of voltage pulses.

### DETAILED DESCRIPTION OF THE INVENTION

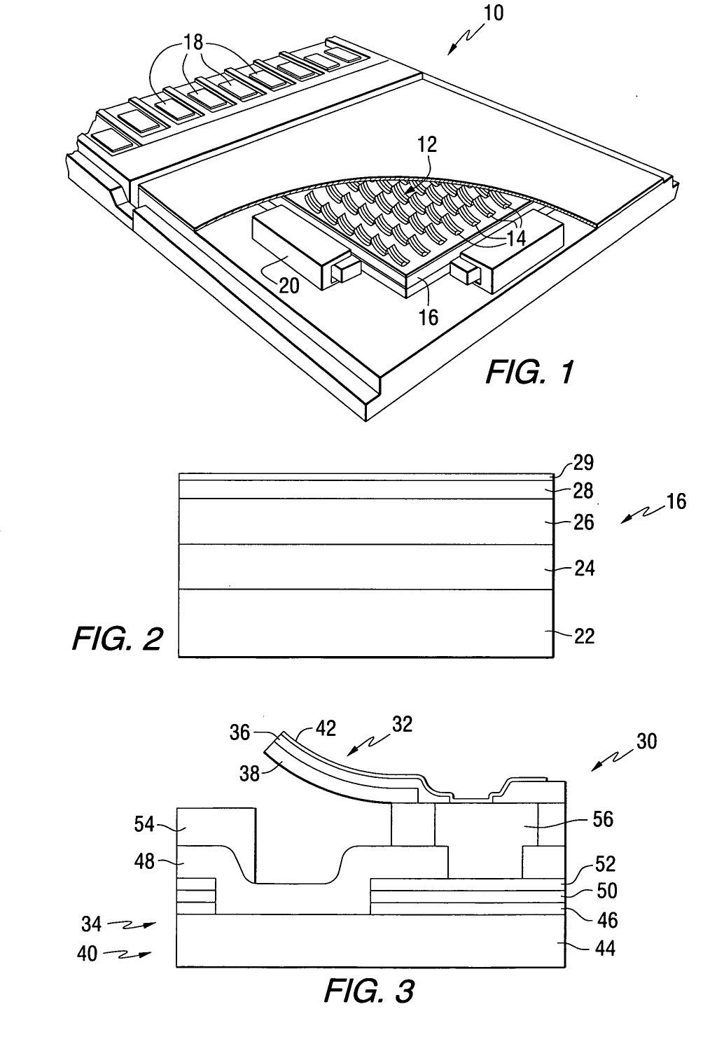

This invention relates to probe storage devices that include a ferroelectric storage medium. FIG. 1 is a perspective view of a ferroelectric storage device 10, which illustrates an implementation of a storage system constructed in accordance with the present invention. In the ferroelectric storage device 10 of FIG. 1, an array 12 of ferroelectric heads 14 is positioned adjacent to a storage medium 16. In the configuration shown in FIG. 1, the array 14 and the medium 16 are planar and extend generally parallel with each other. The array 14 comprises a plurality of electrodes (also referred to as tips), which are operably coupled to connectors 18.

The storage medium 16 is coupled to at least one actuator 20, which is configured to move the medium 16 relative to array 12. This movement causes the ferroelectric heads to be moved relative to the individual ferroelectric domains on medium 16. Each head can include one or more electrodes. To address the destructive readback of data, one technique reserves at least one sector on the storage medium 16, which is available for writing data during a read operation. This available sector is thereby used to reproduce the data, which is being destructively read back. Other techniques rewrite the data to the same domain or to other locations on the media.

FIG. 2 is a side view of a ferroelectric storage medium 14. In this embodiment the storage medium includes a substrate 22, which can be for example Si, a first layer 24 which can be for example SrTiO₃ positioned on the substrate, a layer 26 which can be for example SrRuO₃ positioned on the first layer, and a ferroelectric layer 28 which can be for example lead zirconium titanate (PZT) (PbZrₓTi₁₋ₓ0₃) positioned on the second layer. Other intermediate layers may be used to align the structures between the substrate and the PZT film. In addition, the PZT layer can be doped with other materials, such as lanthanum. While specific example materials are described here, it should be understood that this invention is not limited to the example materials.

Due to electric field spreading in the ferroelectric film, a thin ferroelectric layer is needed for high bit densities. The domain wall stability may improve with thinner films, thereby providing better thermal stability. A top layer 29 can be included to minimize wear of the cantilever electrodes. This material can be liquid or solid lubricant with a high dielectric constant. In one example, the first layer has a thickness of about 100 nm, the second layer has a thickness in the range from about 50 nm to about 100 nm, and the PZT layer has a thickness in the range of 10 to 30 nm. The lubricant layer can have a thickness of 1-3 nm.

FIG. 3 is a schematic illustration of one embodiment of the probe head assembly 30 including a lever 32, and its mechanical and electrical support structures 34, designed for scanning probe storage. The probe lever includes a pair of thin films 36 and 38 (bilayer), deposited on a substrate 40 containing other supporting films and/or electronic circuitry, and whose biaxial stress levels are chosen to ensure that the bilayer wants to bend up from the underlying substrate. This can be achieved by choosing the lower film 36 in the bilayer to have more compressive biaxial stress than the second layer 38 in the bilayer. This stressed bilayer is deposited overlapping a sacrificial layer (not shown in FIG. 3), which is removed selectively by a chemical process, so that the bilayer will bend up from the substrate when the sacrificial layer is removed. The bilayer has a suitable metal or conductive metal-oxide layer 42 (referred to as an electrode or tip) attached to it, so that the lever substrate can be brought in proximity to the ferroelectric media, and the probe metal brought in electrical contact with the media to allow data reading and writing. The probe metal is chosen to be mechanically hard (to resist wear), to be chemically compatible with the media (to avoid media or electrode degradation), and to have high electrical conductivity in both its bulk and surface. Electronic circuitry can be integrated into the substrate.

In this example, the substrate includes a first layer 44 that supports a first conductor adhesion layer 46 and an insulating layer 48, of for example, alumina. A conductor 50 is positioned on the first conductor adhesion layer 46, and a second conductor adhesion layer 52 is positioned on the conductor 50. A passivation layer 54 is provided on the insulating layer. A conductor plug 56 provides an electrical connection between the conductor 50 and the probe 32 through a via in the passivation layer and the insulating layer. While one electrode is shown in this example, it should be understood that multiple electrodes and other structures could be included in the lever.

This invention provides a method and apparatus for waking-up a ferroelectric film. We found that the thermal stability of the data stored in the ferroelectric film is connected to the wake-up effect. In one example, probe-heads in an assembled device can be used to switch the polarization of the entire ferroelectric film several times during a device formatting procedure. In another example, the invention can be used to wake-up (to train) an entire ferroelectric film before using the film in a FE-probe device.

To improve the stability of the remanent polarization of the ferroelectric storage medium in the device of FIG. 1, a voltage signal can be applied to the probes that can scan the entire storage medium. The voltage signal can be a DC voltage or an AC voltage.

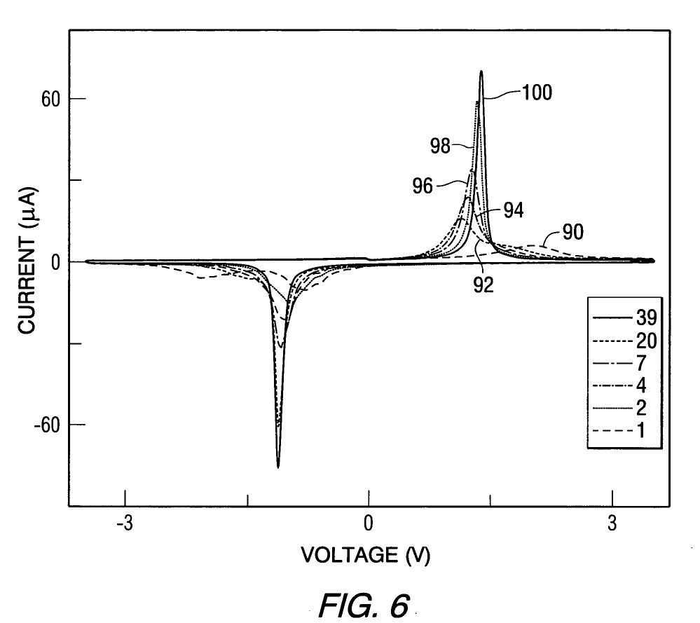

The required voltage magnitude is thickness dependent. The wake-up voltage needs to be larger than the coercive voltage of the film to be able to switch the polarization and train (wake-up) the film. As an example for PZT film thicknesses less than 100 nm the necessary switching voltage is about 2 volts. The number of switching cycles to fully wake-up a ferroelectric thin film depends on the voltage magnitude. FIG. 6 shows that at a moderate voltage just above switching voltage about 25 cycles are needed to entirely wake-up a polycrystalline PZT film. Increasing the voltage by 50% leads to much faster wake-up, and perhaps only 10 cycles will be needed.

Another method can be used to train the ferroelectric film after the thin film deposition and before the film is installed in a storage device, by using a removable electrically conducting electrode to apply a voltage to the film.

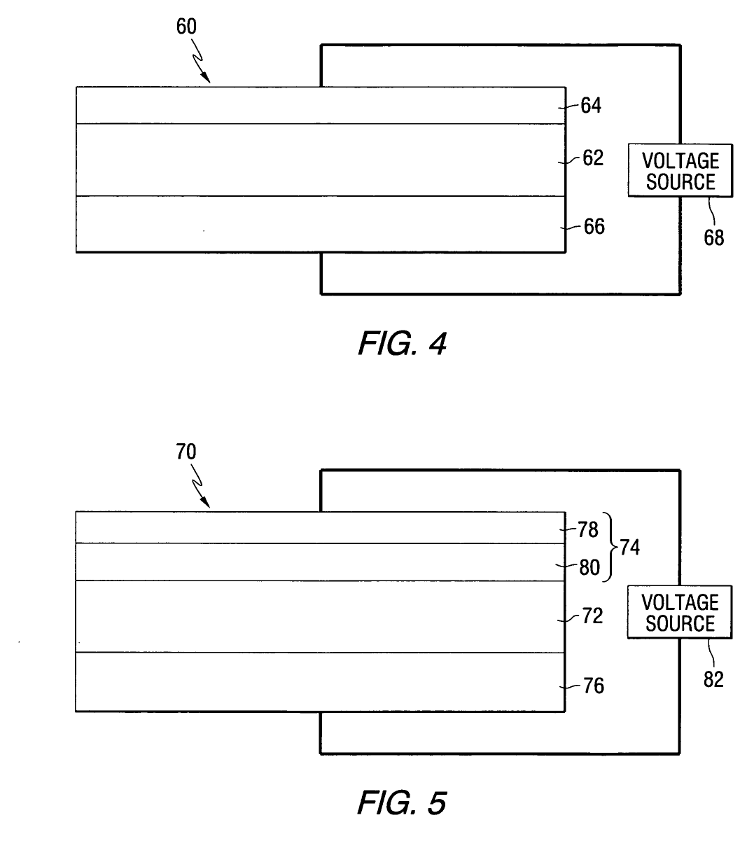

FIG. 4 is a schematic side view of a ferroelectric storage medium 60 having a thin film of ferroelectric material 62 positioned between first and second electrodes 64 and 66. A voltage source 68 is connected to the first and second electrodes to apply an electric field to the thin film of ferroelectric material. After completion of the wake-up procedure, the first electrode is removed. Therefore, the first electrode should be easily removable. For example the first electrode can be a liquid electrode, such as mercury, gallium or an electrolyte.

FIG. 5 is a schematic side view of another ferroelectric storage medium 70 having a thin film of ferroelectric material 72 positioned between first and second electrodes 74 and 76. In this example, electrode 74 comprises a hard metallic layer 78 and a polymer gel layer 80. A voltage source 82 is connected to the first and second electrodes to apply an electric field to the thin film of ferroelectric material. After completion of the wake-up procedure, the first electrode is removed.

In the examples of FIGS. 4 and 5, the ferroelectric film layer can be for example, PbZrTiO₃, SBT, BaTiO₃, or PbTiO₃. The bottom electrode can be for example, SrRuO₃, LSCO, or Pt. The top electrode can be for example SrRuO₃, LSCO, Pt, or Au.

Electrical measurements of the wake-up effect have been carried out on ferroelectric PZT thin film capacitors. In this experiment the ferroelectric thin film was grown on a platinum bottom electrode, and a platinum top electrode was sputtered on to the ferroelectric film to define micrometer-sized capacitors. Switching of the ferroelectric capacitors was measured by detecting the current flow upon applying a triangle voltage excitation waveform to the capacitor. During the ferroelectric switching process a current peak is detected.

FIG. 6 is a graph of an electrical hysteresis measurement of ferroelectric capacitors using platinum top and bottom electrodes. FIG. 6 shows that the current response changes dramatically during the initial switching cycles. After about 20 to 25 cycles there is no further obvious change in the current response and the ferroelectric polarization is considered to be stabilized. At that point, the film has been “woken up” or “trained”. The wake-up effect is strongly correlated to the thermal stability of written data as determined from piezoelectric-response measurements. To obtain the data in FIG. 6, the ferroelectric capacitor, including a 150 nm thick polycrystalline PZT film between platinum bottom and top electrodes, was used. A triangle voltage pulse at 300 Hz was used to switch the ferroelectric thin film capacitor.

In FIG. 6, the first switching of the virgin capacitor is shown as curve 90. The switching current is small and split into two peaks. With subsequent switching cycles the switching peaks become more defined and have higher magnitudes. Curves 92, 94, 96, 98 and 100 show the switching current after 2, 4, 7, 20 and 39 cycles, respectively.

The thermal stability of data written to a ferroelectric thin film has been tested using an atomic force microscope (AFM) to detect the converse piezoelectric effect of the ferroelectric thin film. This permits the measurement of the polarization direction of the film without changing it. This method is known as piezo-response force microscopy (PFM). Initially, small bits were written with the AFM in an untrained area of the ferroelectric film. After twelve days at room temperature the bits were no longer detectable.

Then bits were written on both a trained area and an untrained area of the ferroelectric film. The trained area had been trained using probe heads on a scan-stand by rewriting the area 3 times. After several weeks the bits in the untrained area had relaxed, but in the trained area the bits were stable over this time. This shows that the thermal stability is correlated to the wake-up effect. Thus, it is found that the bits written in the trained area were stable over a month and the bits written in the untrained area disappear after several days.

The above results show that this invention can provide an effective wake-up method by using actual probe heads in the device to switch the entire storage area 3 to 4 times. This method can be performed after the data storage device is fully assembled. In that case, the training of the media could be achieved by applying a DC or AC voltage to all or part of the probe heads while scanning the entire media.

In an alternative example, a wake-up voltage can be applied to the media before assembling the device. In this case a top electrode is deposited on the media forming a capacitor structure, which is used for switching the media several times. After training of the media is complete, the top electrode is removed. The top electrode can be a liquid electrode (e.g. Mercury, Ga, or electrolyte) that is dispersed on to the surface of the ferroelectric film. After training, the electrode is removed by washing of the material with a solvent.

Polymer gel electrolytes can be easily applied to the ferroelectric film (for example by spin coating) and can be removed easily (for example by peeling off or by using solvent). For additional uniformity and easy contacting, a hard metallic top layer can be deposited onto the gel electrolyte. The hard metallic layer can be removed easily together with the polymer gel electrolyte. Typical polymers that can be used for conducting gel electrolytes are poly(methylmethacrylate) (PMMA), poly(acrylonitrile) (PAN), poly(ethylene oxide) (PEO), poly(vinylidene fluoride) (PVdF), and poly(vinylidene fluoride-co-hexafluoropropylene) (PVdF-HFP).

The polymer is an important constituent of polymer gel electrolytes along with salt and solvent. For example, different lithium salts (LiClO₄, LiCF₃SO₃, LiN(CF₃SO₂)₂) can be used together with typical solvents based upon ethylene carbonate (EC), propylene carbonate (PC), dimethylformamide (DMF) and dimethyl sulphoxide (DMSO).

The salt provides ions for conduction. The solvent helps in the dissolution of the salt and also provides a medium for ion conduction. The polymer is added to provide mechanical stability to the electrolytes. The conductivity of a lithium ion conducting polymer gel electrolyte decreases with the addition of polymer, whereas in the case of proton conducting polymer gel electrolytes, an increase in conductivity has been observed with polymer addition. This has been explained to be due to the role of the polymer in increasing viscosity and carrier concentration in these gel electrolytes.

While the invention has been described in terms of several examples, it will be apparent to those skilled in the art that various changes can be made to the described examples without departing from the scope of the invention as set forth in the following claims.

What is claimed is:

1. A method comprising:
providing a ferroelectric storage medium including a film of ferroelectric material; and
repeatedly applying a voltage to the film of ferroelectric material to improve the stability of polarized bits in the film of ferroelectric material.

2. The method of claim 1, wherein the step of repeatedly applying a voltage to the film of ferroelectric material comprises:
placing first and second electrodes on opposite sides of the film of ferroelectric material; and
applying the voltage to the first and second electrodes.

3. The method of claim 1, wherein the first electrode comprises a liquid electrode.

4. The method of claim 1, wherein the first electrode comprises a polymer electrode.

5. The method of claim 4, wherein the polymer electrolyte comprises one of:
poly(methylmethacrylate), poly(acrylonitrile), poly(ethylene oxide), poly(vinylidene fluoride), and poly(vinylidene fluoride-co-hexafluoropropylene).

6. The method of claim 4, wherein the first electrode further comprises a metallic layer.

7. The method of claim 1, wherein the film of ferroelectric material comprises one of:
PbZrTiO₃, SBT, BaTiO₃, and PbTiO₃.

8. The method of claim 1, wherein the step of repeatedly applying a voltage to the film of ferroelectric material comprises:
providing a plurality of electrodes adjacent to a surface of the film of ferroelectric material; and
applying the voltage between the electrodes and the film of ferroelectric material.

9. The method of claim 8, further comprising:
scanning the electrodes over a surface of the film of ferroelectric material.

10. The method of claim 1, wherein the step of repeatedly applying a voltage to the film of ferroelectric material applies at least three cycles of voltage to the film of ferroelectric material.

11. The method of claim 1, wherein the step of repeatedly applying a voltage to the film of ferroelectric material applies a triangular voltage waveform to the film of ferroelectric material.

12. The method of claim 1, wherein the step of repeatedly applying a voltage to the film of ferroelectric material applies a DC voltage to the film of ferroelectric material.

13. An apparatus comprising:
a ferroelectric storage medium including a film of ferroelectric material;
first and second electrodes positioned on opposite sides of the film of ferroelectric material, wherein the first electrode is removable; and
a voltage source for repeatedly applying a voltage to the first and second electrodes to improve the stability of polarized bits in the film of ferroelectric material.

14. The apparatus of claim 13, wherein the first electrode comprises a liquid electrode.

15. The apparatus of claim 13, wherein the first electrode comprises a polymer electrolyte.

16. The apparatus of claim 15, wherein the polymer electrolyte comprises one of:
poly(methylmethacrylate), poly(acrylonitrile), poly(ethylene oxide), poly(vinylidene fluoride), and poly(vinylidene fluoride-co-hexafluoropropylene).

17. The apparatus of claim 13, wherein the first electrode further comprises a metallic layer.

18. The apparatus of claim 13, wherein the film of ferroelectric material comprises one of:
PbZrTiO₃, SBT, BaTiO₃, PbTiO₃.

19. An apparatus comprising:
a ferroelectric storage medium including a film of ferroelectric material;
a plurality of electrodes positioned adjacent to a surface of the film of ferroelectric material; and
a voltage source for repeatedly applying a voltage to the electrodes to improve the stability of polarized bit in the film of ferroelectric material.

20. The apparatus of claim 19, further comprising:
an actuator for scanning the electrodes over a surface of the film of ferroelectric material.
